(19) United States
(12) Patent Application Publication
(10) Pub. No.: US 2012/0015295 A1
(43) Pub. Date: Jan. 19, 2012

(54) INFRARED-SENSITIVE COMPOSITION FOR PRINTING PLATE PRECURSORS

(76) Inventors: Heidi M. Munnelly, Windsor, CO (US); Paul Richard West, Fort Collins, CO (US); Hans-Joachim Timpe, Osterode/Harz (DE); Ursula Muller, Herzberg am Harz (DE); Jianbing Huang, Trumbull, CT (US)

(21) Appl. No.: 13/245,077

(22) Filed: Sep. 26, 2011

Related U.S. Application Data
(63) Continuation of application No. 10/847,708, filed on May 17, 2004, now abandoned.
Application No. 10/847,708 is a continuation-in-part of application No. 10/283,757, filed on Oct. 30, 2002, now abandoned.
Application No. 10/283,757 is a continuation-in-part of application No. 10/217,005, filed on Aug. 12, 2002, now Pat. No. 6,893,797.
Application No. 10/217,005 is a continuation-in-part of application No. 10/040,241, filed on Nov. 9, 2001, now abandoned.

(51) Int. Cl. G03F 7/20; G03F 7/032

(52) U.S. Cl. 430/281.1; 430/302

(57) ABSTRACT

A lithographic printing plate precursor has a substrate and an infrared radiation-sensitive composition comprising a polymeric binder, a free radical polymerizable system consisting of at least one polymerizable component, a compound capable of absorbing infrared radiation, and an initiator system comprising an iodonium salt that is capable of producing free radicals; and at least 1% and up to and including 10% by weight, based on the infrared-sensitive composition, of at least one mono- or polycarboxylic acid having an aromatic moiety.

This application is a continuation of co-pending application Ser. No. 10/847,708, filed May 17, 2004, which is a continuation-in-part of application Ser. No. 10/283,757, filed Oct. 30, 2002, now abandoned, which is a continuation-in-part of application Ser. No. 10/217,005, filed Aug. 12, 2002, now U.S. Pat. No. 6,893,797, which is a continuation-in-part of application Ser. No. 10/040,241, filed Nov. 9, 2001, now abandoned, which is a to continuation-in-part of application Ser. No. 10/131,866, filed Apr. 25, 2002, now U.S. Pat. No. 6,884,568, which is a continuation-in-part of application Ser. No. 09/832,989, filed Apr. 11, 2001, now U.S. Pat. No. 6,864,040, and which is a continuation-in-part of application Ser. No. 10/066,874, filed Feb. 4, 2002, now U.S. Pat. No. 6,846,614.

### 1. FIELD OF THE INVENTION

The present invention relates to an infrared-sensitive composition that is suitable for use in the manufacture of negative-working printing plate precursors. More particularly, the present invention relates to a negative-working printing plate precursor that can be imagewise exposed to infrared-radiation and developed to produce a lithographic printing plate.

### 2. DESCRIPTION OF THE PRIOR ART

Improvement of the properties of radiation-sensitive compositions and parallel improvement of properties of the corresponding printing plate precursors can be addressed in two different ways. In the first approach, the performance and properties of the radiation-sensitive components in the compositions, such as, negative diazo resins or photoinitiators, can be improved. In the second approach, one can embark on a search for novel polymeric compounds, such as, binders, which can control the physical properties of the radiation-sensitive layer. The first approach is of particular importance in cases where the sensitivity of the printing plate precursors is to be adjusted to certain ranges of electromagnetic radiation, since the radiation-sensitivity as well as the shelf-life of the materials are strongly influenced by the nature of such initiator systems.

Recent developments in the field of printing plate precursors have occurred in the area of radiation-sensitive compositions that can be imagewise exposed by means of lasers or laser diodes. This type of exposure does not require the use of films as intermediate information carriers. This is possible because the lasers can be controlled directly by the use of computers.

High-performance lasers or laser diodes that are used in commercially available image-setters emit light in the wavelength ranges from about 800 nm to about 850, typically 830 nm and from about 1060 to about 1120 nm, typically 1064 nm. Accordingly, the printing plate precursors and the initiator systems contained in the printing plate precursors that are imagewise exposed by means of such image-setters, have to be sensitive in the near infrared range. Such printing plate precursors can then be handled in daylight, which significantly facilitates their production and processing.

The radiation-sensitive compositions that are used in such printing plates can be either negative working or positive working. In the negative working printing plates, the exposed areas of the radiation-sensitive compositions are cured upon imagewise exposure. In the developing step only the unexposed areas are removed from the substrate. In the positive working printing plates, the exposed areas of the radiation-sensitive compositions dissolve faster in a given developing agent upon imagewise exposure than the non-exposed areas. This process is referred to as photosolubilization.

To produce a high number of copies in the positive systems, highly crosslinked polymers are generally needed. However, such products are also insoluble in the solvents or solvent mixtures commonly used for plate coating. Therefore, non-crosslinked or slightly crosslinked materials are used to promote solubility.

U.S. Pat. No. 5,491,046, European Patent Documents EP-A-0 672 544, EP-A-0 672 954 and EP-A-0 819 985 describe negative working plates that can be imagewise exposed with infrared lasers. These negative working plates also require a preheating step, i.e., a post exposure heating step, within a very narrow temperature range, which produces only partial crosslinking of the image layer. In order to meet the highest requirements regarding the number of copies and to exhibit sufficient resistance to printing chemicals, an additional heating step, referred to as post development baking, is carried out. During the additional post development baking step, the image layer is further crosslinked.

All of the systems described above have the additional disadvantage of requiring relatively high exposure dose, i.e., ≧150 mJ/cm². For certain applications, such as, news printing, such doses are difficult to deliver while still providing the necessary number of exposed printing plates within a short period of time without inducing ablation.

U.S. Pat. No. 4,997,745 describes photosensitive compositions having a dye absorbing in the visible range and a trihalomethyl-s-triazine compound. However, these compositions do not have sufficient sensitivity in the infrared-range. Moreover, they do not meet today's requirements of high photosensitivity and long shelf life.

U.S. Pat. No. 5,496,903 and German Patent Document DE-A-196 48 313 describe photosensitive compositions which include a dye absorbing in the infrared range and borate or halogenated s-triazine co-initiators. Although these compositions have improved photosensitivity, the printing plates produced thereby do not meet the present-day long shelf life requirement. Thus, after only one month of storage at room temperature, the entire layer of the printing plate appears to have cured to such a degree that an image could no longer be created after exposure and developing of the plate. International Patent Documents WO 99/46310 and WO 99/46301 describe method of preparing UV-curable, highly-branched, functionalized poly(methyl methacrylate) (PMMA) polymers and their use in coating formulations and photoresists. There is no disclosure or teaching in these documents of potential uses of these polymers in infrared-imageable, negative-working lithographic plates.

European Patent Document EP 131,824 describes a photopolymerizable composition based on poly(methyl methacrylate) and multifunctional acrylic monomers for dry film resist and printed circuit board (PCB) applications. These coatings are imagewise exposed with ultraviolet or visible light. There are no teachings of imaging these compositions with wavelengths greater than 700 nm. Other photopolymerizable compositions with initiator systems are described in U.S. Pat. Nos. 5,756,258, 5,545,676 and 5,763,134, Japanese Patent Documents JP-A-11-038633 and JP-A-09-034110 and European Patent Document EP-B-0 522 175.

JP-A-159819, publication date Jun. 12, 2001, discloses a photopolymerizable composition having an alkaline soluble resin, an unsaturated compound and a photopolymerization initiator system, which is initiated with visible light. The initiator system is not infrared initiated.

European Patent Document EP 611,997 describes in a printing plate which the coating contains an acrylic polymer, average molecular weight: 150,000, pentaerythritol triacrylate, a triazine and a squarylium compound (infrared dye) (see Example 1). The acid number or the specific composition of the polymethacrylate polymer is not disclosed.

U.S. Pat. No. 6,153,356 describes a composition, which includes an ethylenically unsaturated compound, near IR-absorbing cyanine dye with barbituric anion group or a thiobarbituric anion group, and photopolymerization initiator. The composition can contain a homopolymer or a copolymer of (meth)acrylic acid and a (meth)acrylate with polymer molecular weights from 10,000 to 500,000 g/mol. The polymer compositions with increasingly high acid numbers are preferred.

U.S. Pat. No. 5,368,990 describes a photopolymerizable composition, which includes an ethylenically unsaturated compound and a photopolymerization initiating composition having a dye and a diaryl iodonium salt as the photopolymerization initiator. The acrylic polymer used in examples 1 to 11 has an acid number of 75.

International Patent Document WO 00/48836 describes an infrared-sensitive composition including an infrared-absorber, free-radical generator system, and a polycarboxylic acid compound. The binders of this patent document have an acid number greater than 70 mg KOH and use a post-exposure heating step prior to developing, as shown in all the examples.

Infrared-sensitive imaging compositions that rely solely on triazines or N-alkoxy pyridinium salts as free radical initiators for polymerization of unsaturated monomers are impracticably slow, necessitating the use of a co-initiator.

U.S. Pat. No. 6,309,792, to Hauck et al, which is International Patent Document WO 00/48836 reports polycarboxylic acid compounds as co-initiators in infrared-sensitive imaging compositions, which significantly improves their photo-reaction speed. There is a need to identify other materials that can serve as co-initiators to improve the reaction speed of such infrared-sensitive imaging compositions. The entire disclosure of U.S. Pat. No. 6,309,792 is incorporated herein by reference.

It is also known to incorporate certain mono-carboxylic acid derivatives such as phenoxyacetic acid and thiophenoxyacetic acid and N-methylindole-3-acetic acid as co-initiators in UV-sensitive imaging compositions, in U.S. Pat. No. 4,366,228, and by Wzyszczynski et al. Macromolecules 2000, 33, 1577-1582. However, such compositions lack infrared-sensitivity. In U.S. Pat. No. 4,366,228, the mono-carboxylic acid is used as the sole initiator, in the absence of any triazine or N-alkoxypyridinium salt co-initiator. Also the monocarboxylic acid compositions are disclosed to be slower than compositions containing N-phenylglycine (NPG). The initiating chromophore in the Macromolecules reference compositions is 4-carboxybenzophenone.

It is also known to incorporate different classes of heteroarylacetic acid compounds in UV-curable silver halide photographic emulsion compositions, and reference is made to U.S. Pat. No. 6,054,260.

### SUMMARY OF THE INVENTION

It is an object of the present invention to provide infrared-sensitive compositions which allow the manufacture of negative printing plate precursors having a long shelf-life, providing a continuously high number of copies and a high degree of resistance to developing chemicals, and which are additionally characterized by high infrared sensitivity resolving power, processability in daylight, fast cure rate and low energy requirements.

Another object underlying this invention is the use of such infrared-sensitive compositions to prepare negative working printing plate precursors, which do not require a post-exposure bake and have excellent latent image stability.

These objects are achieved by a fast curing infrared-sensitive composition according to the present invention that has a low energy requirement.

It is also an objective of the present invention to provide an infrared-sensitive composition comprising, in addition to a polymeric binder, a free radical polymerizable system consisting of at least one member selected from unsaturated free radical polymerizable monomers, oligomers which are free radical polymerizablc, and polymers containing C═C bonds in the back bone and/or in the side chain groups, and an initiator system, wherein the initiator system comprises the following components:
(a) at least one material capable of absorbing infrared radiation
(b) at least one compound capable of producing radicals and
(c) at least one hetero-substituted arylacetic acid co-initiator compound indicated by the following general structures:

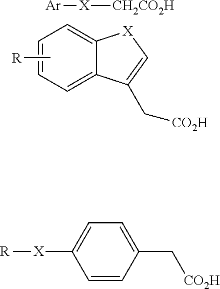

where X is either nitrogen, oxygen or sulfur, Ar is any substituted or unsubstituted aryl ring and R is any substituent.

The present invention provides an infrared-sensitive composition. The infrared-sensitive composition includes:

a polymeric binder; and

a free radical polymerizable system consisting of: at least one component selected from unsaturated free radical polymerizable monomers, oligomers which are free radical polymerizable and polymers containing C═C bonds in the backbone and/or in the side chain groups; and an initiator system including: (a) at least one compound capable of absorbing infrared radiation; (b) at least one compound capable of producing radicals; and (c) at least one carboxylic acid represented by the formula A:

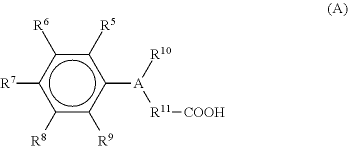

wherein each of R⁵, R⁶, R⁷, R⁸ and R⁹ is independently selected from the group consisting of: hydrogen, alkyl, aryl, halogen, alkoxy, hydroxyalkyl, carboxyalkyl, alkylthio, alkylsulfonyl, sulfonic, alkylsulfonate, dialkylamino, acyl, alkoxycarbonyl, cyano and nitro; wherein R⁵ and R⁶, R⁶ and R⁷, R⁷ and R⁸, or R⁸ and R⁹ together optionally form an aromatic or aliphatic ring; wherein R¹⁰ is selected from the group consisting of: hydrogen, alkyl, aryl, hydroxyalkyl, carboxyalkyl, acyl, alkoxycarbonyl, alkylsulfonyl and alkylsulfonate; or R¹⁰ and its bond together optionally form an electron pair; or R⁹ and R¹¹ together optionally form a ring; wherein R¹¹ is an alkylene group of C₁-C₆ carbon atoms; and wherein R¹⁰ and R¹¹ together optionally form an aliphatic ring; wherein A is a heteroatom selected from the group consisting of: N, O and S; with the proviso that the total acid number of the polymeric binder is 70 mg KOH/g or less.

More particularly, the Infrared-sensitive composition includes: a polymeric binder; and a free radical polymerizable system consisting of at least one component selected from unsaturated free radical polymerizable monomers, oligomers which are free radical polymerizable and polymers containing C═C bonds in the backbone and/or in the side chain groups; and an initiator system including: (a) at least one compound capable of absorbing infrared radiation; (b) at least one compound capable of producing radicals; and (c) at least one polycarboxylic acid having an aromatic moiety substituted with a heteroatom selected from N, O and S and further having at least two carboxyl groups wherein at least one of the carboxyl groups is bonded to the heteroatom via a methylene group; with the proviso that the total acid number of the polymeric binder is 70 mg KOH/g or less.

The present invention further provides a printing plate precursor, which includes:

a substrate; and

coated on the substrate an infrared-sensitive composition including: a polymeric binder; and a free radical polymerizable system consisting of; at least one component selected from unsaturated free radical polymerizable monomers, oligomers which are free radical polymerizable and polymers containing C═C bonds in the backbone and/or in the side chain groups; and an initiator system including: (a) at least one compound capable of absorbing infrared radiation; (b) at least one compound capable of producing radicals; and (c) at least one carboxylic acid represented by the formula A, as defined above:

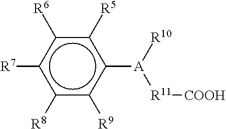

with the proviso that the total acid number of the polymeric binder is 70 mg KOH/g or less.

The present invention still further provides a process for preparing a printing plate, including:

imagewise exposing a printing plate precursor to infrared radiation, the printing plate precursor including: a substrate; and coated on the substrate an Infrared-sensitive composition including: a polymeric binder; and a free radical polymerizable system consisting of: at least one component selected from unsaturated free radical polymerizable monomers, oligomers which are free to radical polymerizable and polymers containing C═C bonds in the backbone and/or in the side chain groups; and an initiator system including: (a) at least one compound capable of absorbing infrared radiation; (b) at least one compound capable of producing radicals; and (c) at least one carboxylic acid represented by the formula A, as defined above,

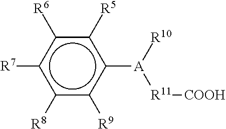

with the proviso that the total acid number of the polymeric binder is 70 mg KOH/g or less; and thereafter; and
developing with a developer solution to produce the printing plate.

The present invention also provides a method for producing an image, including:

coating an optionally pretreated substrate with an Infrared-sensitive composition including: a polymeric binder; and a free radical polymerizable

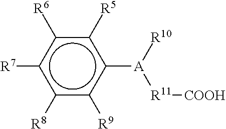

system consisting of at least one component selected from unsaturated free radical polymerizable monomers, oligomers which are free radical polymerizable and polymers containing C═C bonds in the backbone and/or in the side chain groups; and an initiator system including: (a) at least one compound capable of absorbing infrared radiation; (b) at least one compound capable of producing radicals; and (c) at least one carboxylic acid represented by the formula A as defined above,
with the proviso that the total acid number of the polymeric binder is 70 mg KOH/g or less to produce a printing plate precursor;
imagewise exposing the printing plate precursor to infrared radiation to produce an imagewise exposed printing plate precursor; and
developing the precursor with an aqueous developer to obtain a printing plate having thereon a printable lithographic image.

The use of special processors with built in heaters is required for production of plates that require a preheating step (post exposure heating step). Such processors typically have a larger footprint and consume much more energy for operation than the counterparts that are without preheating ovens for post exposure heating. The infrared-sensitivity of compositions according to the present invention, which include poly(methyl methacrylate)-based binders having 70 mg KOH/g or lower acid numbers, are increased by about 50-60 mJ/cm² over those described in WO 00/48836 with infrared-sensitivities of about 120 mJ/cm² for optimal resolution and on-press performance. Thus, the printing plates prepared according to the present invention require only about 60 mJ/cm² for optimal resolution and on-press performance.

Furthermore, in the present invention, improvement in the infrared-sensitivity is achieved without post-exposure bake. Thus, with increased infrared-sensitivity and without a pre-development heating. i.e., post-exposure hake requirement, the number of plates that can be imaged and processed within a period of time is greatly increased. High power imaging lasers are therefore not required for high speed imaging of the plates according to the present invention. With the elimination of the preheating step, establishing proper exposure energies and image quality are also more reproducible.

Latent image stability is also a common problem associated with high speed, photopolymer plates. Typically, depending on the relative humidity, latent images begin fading by about 20 minutes. With the elimination of the post-exposure bake, the latent image stability of the plates described in this Invention has improved by at least three-orders of magnitude (stable for months or more) over those described in WO 00/48836. As a result, the present invention saves time and energy costs to the end user. In addition, the plates according to the present invention are not expected to be sensitive to high humidity conditions.

### DETAILED DESCRIPTION OF THE INVENTION

The present invention describes high-speed, negative-working, infrared-sensitive lithographic plates for commercial printing for which the need for a post-exposure bake requirement has been eliminated and the infrared-sensitivity has been improved by greater than 50% over currently available photopolytnerizable, negative-working, thermal preheat plates.

One embodiment of the present invention is an infrared-sensitive composition, which includes an initiator system. The initiator system includes (i) an infrared absorbing compound (component a); (ii) a radical producing compound (component b); and (iii) a monocarboxylic acid co-initiator (component c).

Another embodiment of the present invention is an infrared-sensitive composition that includes a polymeric binder consisting of a polymer or mixture of polymers having a weight-average molecular weight in the range of 10,000 to 1,000,000 g/mol, with the proviso that the total acid number of the polymeric binder is 70 mg KOH/g or less. The infrared-sensitive composition also includes a free radical polymerizable system. The free radical polymerizable system consist of a polymerizable component, an initiator system having (a) an infrared radiation-absorbing compound, (b) a radical producing compound, and (c) a carboxylic acid co-initiator.

The terms “preheat” or “preheating,” such as, “preheating step” or “preheating oven,” in the context of the present invention refer to “post exposure” but pre-development heating. Thus, a no preheat printing plate is a plate that does not require a heating step between the exposure and the development steps.

### Polymeric Binders

Accordingly, the present invention provides an infrared-sensitive composition including a polymeric binder, which preferably is an acrylic polymer, and a free radical polymerizable system. In some embodiments of the present invention, the total acid number of the polymeric binder is 70 mg KOH/g or less.

Basically all polymers or polymer mixtures known in the art can be used as polymeric binders. Suitable classes of such polymers include, for example, acrylic and methacrylic polymers and copolymers, such as, polymers and copolymers derived from acrylate and methacrylate esters and cellulose polymers, such as, cellulose acetate, cellulose propionate, cellulose butyrate, and cellulose polymers having mixed acyl groups, such as, cellulose acetate propionate. Preferably, the polymers have a weight-average molecular weight in the range of 10,000 to 1,000,000 (determined by GPC).

To achieve good image integrity without a post-exposure bake, some embodiments of the present invention are a polymer having an acid number of 70 mg KOH/g or less. When polymer mixtures are used, the arithmetic average of the individual acid numbers must be 70 mg KOH/g or less. Preferably, the total acid number of the polymeric binder is 50 mg KOH/g or less. More preferably, the total acid number of the polymeric binder is 30 mg KOH/g or less. Especially preferred are polymers with total acid number 10 mg KOH/g or less, including zero. Most preferred polymers are those having a total acid number equal to zero.

In view of possible problems occurring in connection with ink acceptance during the printing process, another embodiment of the present invention includes as a binder a polymer having an acid number >70 mg KOH/g, or when polymer mixtures are used, the arithmetic average of the individual acid numbers be >70 mg KOH/g. A polymer or polymer mixture with an acid number of >110 mg KOH/g is preferred: especially preferred is an acid number is between 140 to 160 mg KOH/g.

Preferably, these polymers are polymers and copolymers derived from acrylate and methacrylate esters, such as, for example, methyl, ethyl, butyl and benzyl esters of acrylic and methacrylic acids. Especially preferred is poly(methyl methacrylate). The composition can further include additional polymers and copolymers. In some embodiments of the present invention, the total acid number must remain 70 mg KOH/g or less.

All molecular weight characterizations are done by gel permeation chromatography (GPC) and the total acid number is determined by summing the weight percents of the original polymer acid numbers, which were determined by titration.

The molecular weight of the polymers derived from acrylate and methacrylate esters can be from 1,000 to 1,000,000 g/mol. Preferably, the molecular weight of the polymers is about 100,000 g/mol, more preferably, the molecular weight of the polymers is about 70,000 g/mol. Especially preferred, are polymers with molecular weights of about 40,000 g/mol. Preferably the polymers can be linear or branched, with a polydispersity of 1 to 5.

The content of the polymeric binder in the infrared-sensitive composition accounts for 20 to 80 wt %, preferably 30 to 60 wt %, more preferably 35 to 45 wt %, of the total solids content of the infrared-sensitive composition.

The free radical polymerizable system has one or more of unsaturated free radical polymerizable monomers, oligomers which are free radical polymerizable and polymers containing C═C bonds in the backbone and/or in the side chain groups and an initiator system.

Suitable unsaturated free radical polymerizable monomers or oligomers include, for example, acrylic or methacrylic acid derivatives with one or more unsaturated groups, preferably esters of acrylic or methacrylic acid in the form of monomers, oligomers or prepolymers. They can be present in solid or liquid form, with one embodiment including solid and highly viscous forms of the polymerizable monomers or oligomers.

The compounds suitable as monomers include, for example, trimethylolpropane triacrylate and methacrylate, pentaerythritol triacrylate and methacrylate, dipentaerythritol monohydroxy pentaacrylate and methacrylate, dipentaerythritol hexaacrylate and methacrylate, pentaerythritol tetraacrylate and methacrylate, ditrimethylolpropane tetraacrylate and methacrylate, diethyleneglycol diacrylate and methacrylate, triethyleneglycol diacrylate and methacrylate or tetraethyleneglycol diacrylate and methacrylate.

Suitable oligomers and/or prepolymers include urethane acrylates and methacrylates, such as, the reaction product of Desmodur® N-100, hydroxyethyl acrylate and pentaerythritol triacrylate; epoxide acrylates and methacrylates; polyester acrylates and methacrylates; polyether acrylates and methacrylates; and unsaturated polyester resins.

In addition to monomers and oligomers, polymers having C═C bonds in the backbone and/or in the side chains can also be used. Examples include: reaction products of maleic anhydride-olefin-copolymers and hydroxyalkyl(meth)acrylates, polyesters containing an allyl alcohol group, reaction products of polymeric polyalcohols and isocyanatoalkyl (meth)acrylates, unsaturated polyesters, (meth)acrylate terminated polystyrenes, poly(meth)acrylics and polyethers.

The weight ratio of the free radical polymerizable monomers or oligomers is from about 25 wt % to about 75 wt %, preferably from about 35 wt % to about 60 wt %, more preferably from about 45 wt % to about 55 wt %, of the total solids content of the IR-sensitive composition.

### Infrared Absorbers

Useful infrared absorbing compounds typically have a maximum absorption wavelength in some part of the electromagnetic spectrum greater than about 750 nm; more particularly, their maximum absorption wavelength is in the range from 780 to 1100 nm.

Preferably, component (a) includes at least one compound selected from triarylamine dyes, thiazolium dyes, indolium dyes, oxazolium dyes, cyanine dyes, polyaniline dyes, polypyrrole dyes, polythiophene dyes, leuco dyes and phthalocyanine pigments and dyes.

It is more preferred that component (a) includes a cyanine dye of the formula (I):

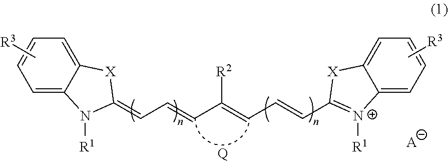

wherein each X can independently be S, O, NR or C(alkyl)₂;

each R¹ can independently be an alkyl, an alkylsulfonate or an alkylammonium group;

R² can be hydrogen, halogen, SR, SO₂R, OR, or NR₂;

each R³ can independently be a hydrogen, an alkyl group, COOR, OR, SR, SO₃⁻, NR₂, a halogen, or an optionally substituted benzofused ring;

A⁻ represents an anion;

-Q- represents an optional bridge completing a five- or six-membered carbocyclic ring;

wherein each R can independently be hydrogen, an alkyl and an aryl group; and

wherein each n can independently be 0, 1, 2 or 3.

If R¹ is an alkylsulfonate group, A⁻ can be absent due to the formation of an inner salt and an alkali metal cation would be necessary as a counterion. If R¹ is an alkylammonium group, a second anion would be necessary as counterion. The second anion can be the same as K or it can be a different anion.

These dyes absorb in the range of 750 to 1100 nm. Dyes of the formula (I), which absorb in the range of 780 to 860 nm, are preferred.

Particularly preferred infrared dyes of the formula (I) include compounds in which:
X is preferably a C(alkyl)₂ group;
R¹ is preferably an alkyl group with 1 to 4 carbon atoms;
R² is preferably SR;
R³ is preferably hydrogen;
R is preferably an alkyl or aryl group: especially preferred is a phenyl group;
-Q- represents an optional bridge completing a five- or six-membered carbocyclic ring; and
counterion A⁻ is preferably a chloride ion or a tosylate anion.

Especially preferred include infrared dyes that are symmetrical, such as the symmetrical dyes represented by formula (I). Examples of such especially preferred dyes include:
2-[2-[2-phenylsulfonyl-3-[2-(1,3-dihydro-1,3,3-trimethyl-2H-indol-2-ylidene)-ethylidene]-1-cyclohexen-1-yl]-ethenyl]-1,3,3-trimethyl-3H-indoliumchloride;
2-[2-[2-thiophenyl-3-[2-(1,3-dihydro-1,3,3-trimethyl-2H-indol-2-ylidene)-ethylidene]-1-cyclohexen-1-yl]-ethenyl]-1,3,3-trimethyl-3H-indoliumchloride;
2-[2-[2-thiophenyl-3-[2-(1,3-dihydro-1,3,3-trimethyl-2H-indol-2-ylidene)-ethylidene]-1-cyclopenten-1-yl]-ethenyl]-1,3,3-trimethyl-3H-indoliumtosylate;
2-[2-[2-chloro-3-[2-ethyl-(3H-benzthiazole-2-ylidene)-ethylidene]-1-cyclohexen-1-yl]ethenyl]-3-ethyl-benzthiazolium-tosylate; and
2-[2-[2-chloro-3-[2-(1,3-di hydro-1,3,3-trimethyl-2H-indol-2-ylidene)-ethylidene]-1-cyclohexen-1-yl]-ethenyl]-1,3,3-trimethyl-3H-indolium tosylate.

Additional infrared absorbers that are useful in the compositions of the present invention include the following compounds:

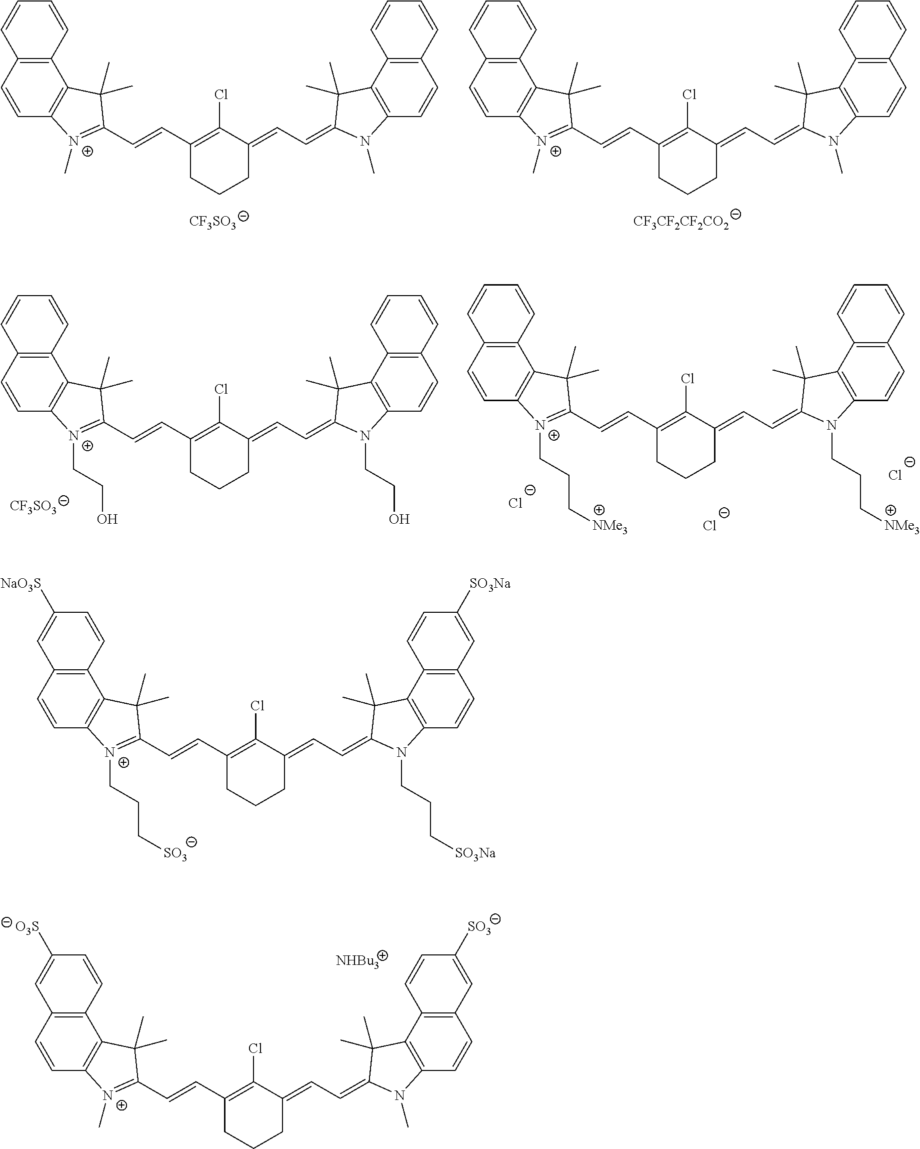

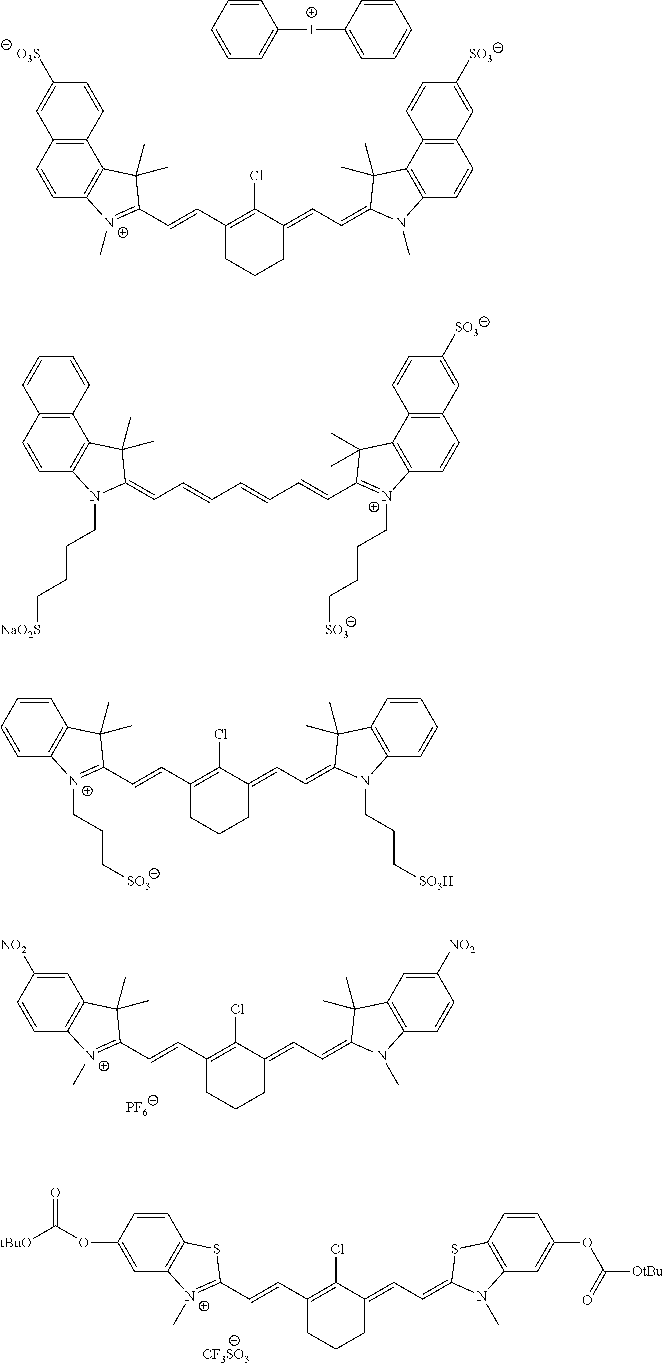

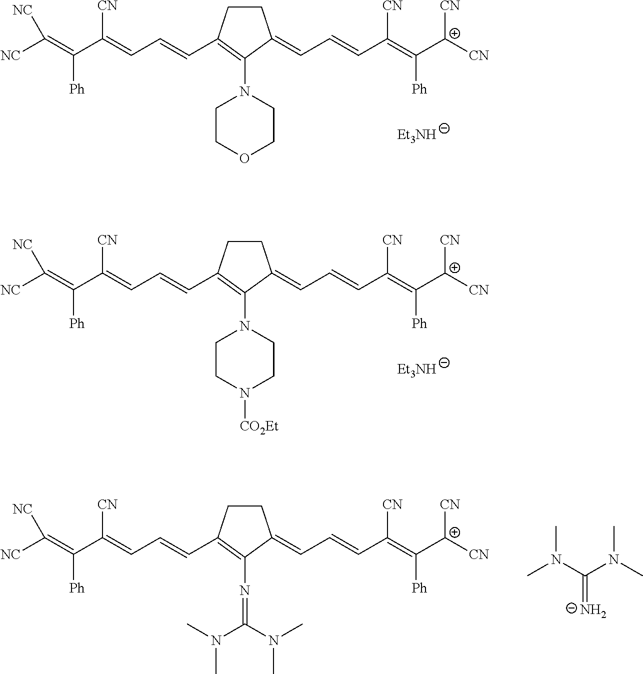

The infrared absorber (a) is preferably present in the infrared-sensitive composition in an amount of from about 0.05 wt % to about 20 wt %, preferably from about 0.5 to 8 wt %, and more preferably from about 1.0 to 3 wt %, based on the total solids content of the infrared-sensitive composition.

### Radical Producers

Another essential component of the initiator system is the compound capable of producing radicals, component (b). Preferably this compound is selected from polyhaloalkyl substituted compounds and azinium compounds. Especially preferred are polyhaloalkyl-substituted compounds. These are compounds that contain either one poly halogenated or several monohalogenated alkyl substituents. The halogenated alkyl group preferably has 1 to 3 carbon atoms. Especially preferred is a halogenated methyl group.

In the present free radical polymerizable system the radical is formed between component (a) and component (b) and the carboxylic acid. In order to achieve a high degree of radiation sensitivity, the presence of all three components is indispensable. It was found that completely radiation-insensitive compositions were obtained when component (b) was missing.

The absorption properties of the polyhaloalkyl-substituted compound fundamentally determine the daylight stability of the infrared-sensitive composition. Compounds having a UV/VIS absorption maximum of >330 nm result in compositions which can no longer be completely developed after the printing plate has been kept in daylight for 6 to 8 minutes and then been reheated. Such compositions could be imagewise exposed not only with infrared but also with UV radiation. If a high degree of daylight stability is desired, polyhaloalkyl-substituted compounds are preferred which do not have a UV/VIS absorption maximum at >330 nm.

The azinium compounds include an azinium nucleus, such as a pyridinium, diazinium, or triazinium nucleus. Suitable such compounds are disclosed in GB 2,083,832, the disclosure of which is incorporated herein by reference. The azinium nucleus can include one or more aromatic rings, typically carbocyclic aromatic rings, fused with an azinium ring. In other words, the azinium nuclei include quinolinium, isoquinolinium, benzodiazinium, and naphthodiazonium nuclei. To achieve the highest attainable activation efficiencies per unit of weight it is preferred to employ monocyclic azinium nuclei.

A quaternizing substituent of a nitrogen atom in the azinium ring is capable of being released as a free radical upon electron transfer from the photosensitizer to the azinium compound. In one preferred form the quaternizing substituent is an oxy substituent. The oxy substituent (—O—R), which quaternizes a ring nitrogen atom of the azinium nucleus, can be selected from among a variety of synthetically convenient oxy substituents. The moiety R can, for example, be an alkyl radical, which can be substituted; for example aralkyl and sulfoalkyl groups are contemplated. Most preferred oxy substituents (—O—R) contain 1 or 2 carbon atoms.

Examples of especially suitable component (b) for the compositions of the present invention include:
N-methoxy-4-phenylpyridinium tetratluoroborate;
tribromomethylphenylsulfone;
1,2,3,4-tetrabromo-n-butane;
2-(4-methoxyphenyl)-4,6-bis(trichloromethyl)-s-triazine;
2-(4-chlorophenyl)-4,6-bis(trichloromethyl)-s-triazine;
2-phenyl-4,6-bis(trichloromethyl)-s-triazine;
2,4,6-tri-(trichloromethyl)-s-triazine;
2,4,6-tri-(tribromomethyl)-s-triazine;
2-hydroxytetradecyloxyphenyl phenyliodonium hexafluoroantimonate;
   and
2-methoxy-4-phenylaminobenzenediazonium hexafluorophosphate.

Further, the following compounds are useful as initiators (b) in the compositions of the present invention:

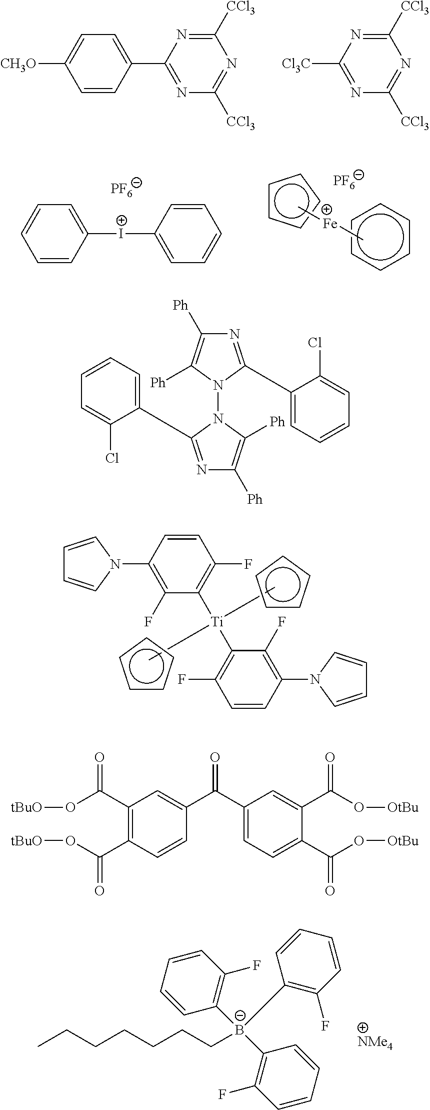

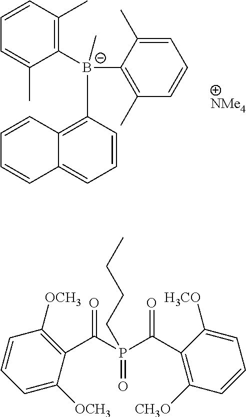

Component (b) is preferably present in the infrared-sensitive composition in an amount of from 2 to 15 wt %, based on the total solids content of the infrared-sensitive composition especially preferred is amount of from 4 to 7 wt %.

a

### Co-Initiators

The carboxylic acid, which is component (c), can be any carboxylic acid that is capable of serving in the initiator system as a co-initiator with the compound capable of producing radicals. In one embodiment of the present invention, the carboxylic acid has an aromatic moiety substituted with a heteroatom selected from N, O and S. In another embodiment the carboxylic acid includes at least two carboxyl groups (a polycarboxylic acid) at least one of which is bonded to the heteroatom via a methylene group. While polycarboxylic acids are preferred, mono carboxylic, i.e., having one carboxylic acid group, are also suitable for use in the infrared-sensitive compositions of the present invention. The preferred examples of the monocarboxylic acids include N-aryl-α-amino carboxylic acids, such as, PhNHCH₂COOH and preferred examples of the polycarboxylic acids include N-phenyliminodiacetic acid. Further examples of preferred carboxylic acids include:
(p-acetamidophenylimino)diacetic acid;
3-(bis(carboxymethyl)amino)benzoic acid;
4-(bis(carboxymethyl)amino)benzoic acid;
2-((carboxymethyl)phenylamino)benzoic acid;
2-((carboxymethyl)phenylamino)-5-methoxybenzoic acid;
3-(bis(carboxymethyl)amino-2-naphthalene-carboxylic acid;
N-(4-aminophenyl)-N-(carboxymethyl)glycine;
N,N′-1,3-phenylenebisglycine;
N,N′-1,3-phenylenebis(N-(carboxymethyl))glycine;
N,N′-1,2-phenylenebis(N-(carboxymethyl))glycine;
N-(carboxymethyl)-N-(4-methoxyphenyl)glycine;
N-(carboxymethyl)-N-(3-methoxyphenyl)glycine;
N-(carboxymethyl)-N-(3-hydroxyphenyl)glycine;
N-(carboxymethyl)-N-(3-chlorophenyl)glycine;
N-(carboxymethyl)-N-(4-bromophenyl)glycine;
N-(carboxymethyl)-N-(4-chlorophenyl)glycine;
N-(carboxymethyl)-N-(2-chlorophenyl)glycine;
N-(carboxymethyl)-N-(4-ethylphenyl)glycine;
N-(carboxymethyl)-N-(2,3-dimethylphenyl)glycine;
N-(carboxymethyl)-N-(3,4-dimethylphenyl)glycine;
N-(carboxymethyl)-N-(3,5-dimethylphenyl)glycine;
N-(carboxymethyl)-N-(2,4-dimethylphenyl)glycine;
N-(carboxymethyl)-N-(2,6-dimethylphenyl)glycine;
N-(carboxymethyl)-N-(4-formylphenyl)glycine;
N-(carboxymethyl)-N-ethylanthranilic acid;
N-(carboxymethyl)-N-propylanthranilic acid;
5-bromo-N-(carboxymethyl)anthranilic acid;
N-(2-carboxyphenyl)glycine;
o-dianisidine-N,N,N′,N′-tetraacetic acid;
N,N′-(1,2-ethanediyibis(oxy-2,1-phenylene))bis(N-(carboxymethyl)glycine);
4-carboxyphenoxyacetic acid;
catechol-O,O′-diacetic acid;
4-methylcatechol-O,O′-diacetic acid;
resorcinol-O,O′-diacetic acid;
hydroquinone-O,O′-diacetic acid;
α-carboxy-o-anisic acid;
4,4′-isopropylydenediphenoxyacetic acid;
2,2′-(dibenzofuran-2,8-diyldioxy)diacetic acid;
2-(carboxymethylthio)benzoic acid;
5-amino-2-(carboxymethylthio)benzoic acid; and
3-((carboxymethyl)thio)-2-naphtalenecarboxylic acid.

The preferred polycarboxylic acids include N-arylpolycarboxylic acids, particularly those having the following formula (B):

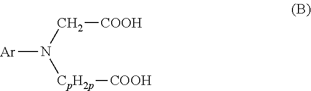

wherein Ar is a mono-, poly- or unsubstituted aryl group and p is an integer from 1 to 5, and those of the formula (C):

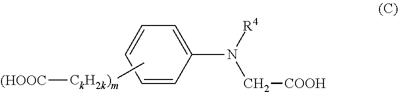

wherein R⁴ represents hydrogen or a C₁-C₆ alkyl group and k and m each represent an integer from 1 to 5.

Possible substituents of the aryl group in formula (B) are C₁-C₃ alkyl groups, C₁-C₃ alkoxy groups, C₁-C₃ thioalkyl groups and halogen atoms. The aryl group can have 1 to 3 identical or different substituents and preferably, p is 1, and preferably, Ar represents a phenyl group. In formula (C), m is preferably 1 and R⁴ preferably represents hydrogen. The most preferred polycarboxylic acid is N-phenyliminodiacetic acid.

In one embodiment, the carboxylic acid co-initiator is a monocarboxylic acid having the formula Ar—X—CH₂COO₂H, where “Ar” is a substituted or unsubstituted aromatic moiety and “X” is defined as oxygen or sulfur.

Alternative embodiments featuring the monocarboxylic acids have the formula:

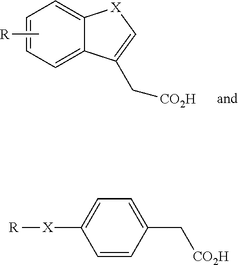

In other embodiments of the present invention, the monocarboxylic acids include phenoxyacetic acid, (phenylthio) acetic acid, N-methylindole-3-acetic acid, (2-methoxyphenoxy) acetic acid. (3,4-dimethoxyphenylthio) acetic acid, and 4-(dimethylamino) phenylacetic acid.

The mono or polycarboxylic acid is preferably present in the infrared-sensitive composition in an amount of from 1 to 10 wt %, especially preferred 1.5 to 3 wt %, based on the total solids content of the infrared-sensitive composition.

### Dyes

The infrared-sensitive composition can further include dyes for improving the contrast of the image. Suitable dyes are those that dissolve well in the solvent or solvent mixture used for coating or are easily introduced in the disperse form of a pigment. Suitable contrast dyes include rhodamine dyes, triarylmethane dyes, methyl violet, anthroquinone pigments and phthalocyanine dyes and/or pigments. The dyes are preferably present in the infrared-sensitive composition in an amount from 1 to 15 wt %, preferably in an amount from 2 to 7 wt %.

### Plasticizers

The infrared-sensitive compositions of the present invention can further include a plasticizer. Suitable plasticizers include dibutyl phthalate, triaryl phosphate and dioctyl phthalate. If a plasticizer is used, it is preferably present in an amount in the range of 0.25 to 2 wt %.

### Use of the Infrared-Sensitive Composition

The infrared-sensitive compositions of the present invention are suitable for use in the manufacture of printing plate precursors. They can be used in recording compositions for creating images on suitable substrates and receiving sheets, for creating reliefs that can serve as printing plates, screens and the like. In addition, they can be used in radiation curable varnishes for surface protection and in formulations of radiation-curable printing inks.

### Substrates

For the manufacture of offset printing plate precursors, any conventional substrate can be used. Preferably, the support should be strong, stable and flexible. It should also resist dimensional change under conditions of use so that color records will register in a full color image. It can be any self-supporting materials, including polymeric films, such as, polyethylene terephthalate film, ceramics, metals, stiff papers or a lamination of any of these materials. Examples of such metal supports include aluminum, zinc, titanium and alloys thereof.

The use of an aluminum substrate is especially preferred. Preferably, the surface of the aluminum substrate is first roughened. The roughening can be carried out by brushing in a dry state or by brushing with an abrasive suspension. It can be also carried out electrochemically, e.g., in an hydrochloric acid electrolyte. The roughened substrate plates, which can optionally be anodically oxidized in sulfuric or phosphoric acid, are then subjected to a hydrophilizing after-treatment, preferably in an aqueous solution of polyvinylphosphonic acid or phosphoric acid. Preferably, the substrate is a pretreated, hydrophilic substrate, such as, aluminum or polyester.

The details of the above-mentioned substrate pretreatment are well known to the person skilled in the art. The dried substrate is then coated with the infrared-sensitive composition of the present invention using an organic solvent or solvent mixtures to produce a coated layer preferably having a dry weight of from about 0.5 to about 4.0 g/m², more preferably from about 0.8 to about 3.0 g/m², and most preferably from about 1.0 to about 2.5 g/m².

An oxygen-impermeable layer can be applied on top of the infrared-sensitive layer by methods known in the art. In the context of the present invention the term “oxygen-impermeable layer” includes layers that have low permeability to oxygen. The oxygen-impermeable layer can include polyvinyl alcohol, a polyvinyl alcohol/polyvinyl acetate copolymer, polyvinyl pyrrolidone, polyvinyl pyrrolidone/polyvinyl acetate copolymer, polyvinyl methyl ether, polyacrylic acid and gelatin. The dry layer weight of the oxygen impermeable layer is preferably 0.1 to 4 g/m², more preferably 0.3 to 2 g/m². This overcoat is not only useful as oxygen barrier but also it protects the plate against ablation during exposure to infrared radiation.

### Printing Plate Precursor

The printing plate precursors obtained in this manner are imagewise exposed using, for example, semiconductor lasers or laser diodes that emit in the range of from about 800 nm to about 1,100 nm. Such a laser beam can be digitally controlled via a computer, i.e., it can be turned on or off so that an imagewise exposure of the plates can be effected via stored digitalized information in the computer. Accordingly, the infrared-sensitive compositions of the present invention are suitable for producing what is referred to as computer-to-plate (ctp) printing plates. Alternatively, the thermally imageable element may be imaged using an apparatus containing a thermal printing head. An imaging apparatus suitable for use in conjunction with thermally imageable elements includes at least one thermal head but would usually include a thermal head array, such as, the TDK Model No. LV5416, which can be used in thermal fax machines and sublimation printers, and the GS618-400 thermal plotter (Oyo Instruments, Houston, Tex., USA). Suitable commercially available imaging devices include imagesetters, such as, CREO TRENDSETTERS(CREOSCITEX, British Columbia, Canada) and the GERBER CRESCENT 42T.

After the printing plate precursor is imagewise exposed, it can be optionally heated to a temperature from about 85° C. to about 135° C. for a brief period of time in order to effect complete curing of the exposed areas. Depending on the temperature applied, this would take only about 20 to about 100 seconds. Then the plates are developed in the aqueous developing compositions by methods known to those skilled in the art, such as those described in U.S. Pat. No. 5,035,982. Thereafter, the developed plates can be treated with a preservative. The preservatives are aqueous solutions of hydrophilic polymers, wetting agents and other additives.

The following examples serve to provide a detailed demonstration of the negative-working lithographic plates, which have improved IR-sensitivity and improved latent image stability but have no post-exposure baking requirement.

### Example 1

A base coat solution containing the following components was prepared as shown in Table 1.

TABLE 1
Example 1 Base Coat Formulation

| Parts by | |
|---|---|
| Weight | Component |
| 3.55 | Urethane acrylate prepared by reacting 1-methyl-2,4-bis- |
| | isocyanate benzene (Desmodur N100 ®; Bayer) with |
| | hydroxyethyl acrylate and pentaerythritol triacrylate |
| 0.74 | Sartomer 355 (multi-functional acrylic monomer; Sartomer |
| | Co., Inc., ditrimethylolpropane tetraacrylate) |
| 3.24 | Elvacite 4026 (highly-branched poly(methyl methacrylate) |
| | with an acid number of 0, MW 32.5K, MW/Mn = 4.3; from |
| | Ineos Acrylics, Inc., Cordova, TN) |
| 0.40 | 2-(4-methoxyphenyl)-4,6-bis(trichloromethyl)-2-triazine |
| 0.22 | N-phenyliminodiacetic acid |
| 0.08 | 2-[2-[2-thiophenyl-3-[2-(1,3-dihydro-1,3,3-trimethyl-2H- |
| | indol-2-ylidene)-ethylidene]-1-cyclohexen-1-yl]-ethenyl]- |
| | l,3,3-trimethyl-3H-indoliumchloride |
| 0.10 | Crystal Violet |
| 0.02 | Byk307 (modified polysiloxane; Byk Chemie) |
| 13.75 | Methyl ethyl ketone |
| 22.91 | Toluene |
| 54.99 | 1-methoxy-2-propanol |

The above solution was coated on electrochemically grained and anodized aluminum which had a polyvinylphosphonic acid post-treatment with a wire-wound rod to yield a dry coating weight of 2 g/m². The plates were dried at about 94° C. for 60 sec residence time in a Ranar conveyor oven. The overcoat solution was prepared from 5.26 parts of Airvol® 203, 0.93 parts polyvinylimidazole, 3.94 parts isopropanol, and 89.87 parts water. After applying the overcoat in a similar manner as the base coat, the plates were dried at 94° C. for 90 seconds residence time in a Ranar conveyor oven. The overcoat also had a dry coating weight of 2 g/m². These plates were imaged on a Creo TRENDSETTER imagesetter 3244× at 2 W and 35 to 250 rpm. This exposure series ranged from 20 to 150 mJ/cm². The minimum exposure energy necessary to achieve maximum processed density was about 26 mJ/cm². Plates were processed without a post-exposure bake with a developer solution as described in Table 2.

TABLE 2
Example 1 Developer Formulation

| | Parts by |
|---|---|
| Component | Weight |
| Water | 83.58 |
| Sodium Xylene Sulfonate (40%) | 3.83 |
| Sodium Toluene Sulfonate (40%) | 1.73 |
| Benzyl Alcohol | 3.41 |
| Poly(vinyl Alcohol) 205 (10%) | 4.16 |
| Diethanolamine (85%) | 0.36 |
| Sodium Dodecylbenzene Sulfonate | 0.27 |
| Triton ® H-66 (50%) (from Rohm & Haas) | 2.66 |

Plates mounted on a Miehle sheet-fed press produced about 5,000 excellent reproductions under accelerated wearing conditions using black ink containing 1.5 wt % calcium carbonate. The number of impressions increased to about 50,000 under accelerated wearing conditions by UV-curing the plates prior to mounting on press. UV-curing was accomplished by flood exposing the plates on an Olec vacuum frame (5 kW bulb) with 22 units.

### Examples 2-4

The base coat formulations for examples 2, 3 and 4 were prepared as described in Example 1 except that in place of the Elvacite® 4026, poly(methyl methacrylate) polymers (both from Aldrich) with a MW of either 10 K (Example 2) or 30 K (Example 3) or (methyl methacrylate)/methacrylic acid copolymer (from Ineos Acrylics, Inc.) with a MW about 35K (Example 4) were substituted. Each of these polymers had polydispersities from 1-1.8 and an acid number of 0 (Examples 2 & 3) and 9 (Example 4). The base coat was applied and the overcoat prepared and applied as described in Example 1. Plates were imaged and processed as described in Example 1. The minimum exposure energies necessary to achieve maximum processed density were about 35 mJ/cm², about 26 mJ/cm² and about 40 mJ/cm² for Examples 2, 3 and 4, respectively.

### Comparative Example 1

In this example, the Elacite® 4026 in Example 1 base coat formulation was substituted by 1.62 parts Jagotex MA 2814/MP (terpolymer with an acid number of 125 mg KOH/g and MW about 90K; Ernst Yager GmbH & Co.) and 1.62 parts Joncryl® 683 (acrylic polymer with an acid number of 150 mg KOH/g and MW about 10K; SC Johnson & Son, Inc.). The Jagotex terpolymer contains 43.3% styrene, 45% methyl methacrylate, and 11.7% acrylic acid. The base coat was applied and overcoat prepared and applied as described in Example 1. Plates were imaged as described in Example 1. Plates were processed through a Technigraph processor charged with 980 developer (Kodak Polychrome Graphics) equipped with a preheat oven which allowed plates to reach a backside temperature of 125° C. The minimum exposure energy necessary to achieve maximum processed density was about 50 mJ/cm². A second plate prepared as described above was processed through the same Technigraph processor with the preheat oven disabled. No coating was retained following processing.

### Comparative Examples 2 and 3

In these examples, the Elvacite® 4026 in Example 1 base coat formulation was substituted by either Joncryl® 683 (acrylic polymer with an acid number of 150 mg KOH/g and MW about 10,000 g/mol; SC Johnson & Son, Inc.) (Comparative Example 2) or Jagotex MA 2814/MP (terpolymer with an acid number of 125 mg KOH/g and MW about 90K; Ernst Yager GmbH & Co.) (Comparative Example 3). The Jagotex terpolymer contains 43.3% styrene, 45% methyl methacrylate, and 11.7% acrylic acid. The base coat was applied and overcoat prepared and applied as described in Example 1. Plates were imaged as described in Example 1. Plates were processed through a Technigraph processor charged with 980 developer with the preheat oven disabled. No coating was retained following processing for either Comparative Example 2 or Comparative Example 3.

### Examples 5-7

The base coat formulations for Examples 5, 6 and 7 were prepared as described in Example 1 except that N-phenylgylcine (Eastman Kodak) (Example 5), 1H-1,2,4-triazole-3-thiol (Aldrich) (Example 6) or (2-methoxyphenoxy) acetic acid (Aldrich) (Example 7) was used in place of N-phenyliminodiacetic acid. The base coat was applied and overcoat prepared and applied as described in Example 1. Plates were imaged and processed as described in Example 1. The minimum exposure energies necessary to achieve maximum processed density were about 30 mJ/cm², about 30 mJ/cm² and about 40 mJ/cm² for Examples 5, 6 and 7, respectively.

### Comparative Examples 4-6

The base coat and overcoat formulations for Comparative Examples 4, 5, and 6 were prepared and coated as described in Comparative Example 1 except that N-phenylgylcine (Eastman Kodak) (Comparative Example 4), 1H-1,2,4-triazole-3-thiol (Aldrich) (Comparative Example 5) or (2-methoxyphenoxy) acetic acid (Aldrich) (Comparative Example 6) was used in place of the N-phenyliminodiacetic acid. The plates were imaged as described in Example 1.

The plates were processed through a Technigraph processor charged with 980 developer (Kodak Polychrome Graphics) equipped with a preheat oven which allowed plates to reach a backside temperature of 125° C. The minimum exposure energy necessary to achieve maximum processed density was 120 mJ/cm² (Comparative Example 4), 98 mJ/cm² (Comparative Example 5), and 90 mJ/cm² (Comparative Example 6).

The consequences of altering this component of the initiator system produced much greater effect in Comparative Examples 4, 5, and 6 where the total acid number of the binders was 138 mg KOH/g than in Examples 5, 6, and 7 where the binder had an acid number of zero.

### Examples 8-11

The base coat formulations for Examples 8, 9, 10 and 11 were prepared as described in Example 1 except that in place of 2-(4-methoxyphenyl)-4,6-bis(trichloromethyl)-2-triazine, 2-(4-methylthiophenyl)-4,6-bis(trichlomethyl)-1,3,5-triazine (Lancaster) (Example 8), 2-methoxy-4-(phenylamino)benzenediazonium hexafluorophosphate (Example 9), diphenyl iodonium hexafluorophosphate (prepared according to the method of J. Crivello et al., J. Org. Chem., Vol. 43, 3055 (1978)) (Example 10) or 2,2′-bis(o-chlorophenyl)-4,5,4′,5′-tetraphenyl biimidazole (Charkit Chemical Corp.) (Example 11) was substituted. The base coat was applied and overcoat prepared and applied as described in Example 1. Plates were imaged and processed as described in Example 1. The minimum exposure energies necessary to achieve maximum processed density were about 26 mJ/cm², about 47 mJ/cm² and about 108 mJ/cm² for Examples 8, 9, and 10, respectively. An image was produced when 2,2′-bis(o-chlorophenyl)-4,5,4′,5′-tetraphenyl biimidazole was incorporated into the base coat formulation, although the image was not completely resistant to the developer described in Example 1. The estimated minimum exposure energies necessary to achieve maximum processed density was about 100 mJ/cm² for Example 11.

### Comparative Example 7

The base coat formulation for Comparative Example 7 was prepared as described in Comparative Example 1 except that in place of 2-(4-methoxyphenyl)-4,6-bis(trichloromethyl-triazine, 2-methoxy-4-(phenylamino)benzenediazonium hexafluorophosphate was used. The base coat was applied and overcoat prepared and applied as described in Example 1. Plates were imaged as described in Example 1. Plates were processed through a Technigraph processor charged with 980 developer (Kodak Polychrome Graphics) equipped with a preheat oven which allowed plates to reach a backside temperature of 125° C. No image resulted as the entire coating prematurely cured. When this plate was processed with the Technigraph preheat oven disabled the entire coating was also prematurely cured and no image present. This was an unfavorable result as compared to Example 9 with the poly(methyl methacrylate) based polymers which produced acceptable images on the plate.

### Example 12

The base coat formulation for Example 12 was prepared as described in Example 1 except that in place of Elvacite® 4026, poly(benzyl methacrylate) (acid number 0 mg KOH/mg from Aldrich) was substituted. The base coat was applied and overcoat prepared and applied as described in Example 1. Plates were imaged and processed as described in Example 1. The minimum exposure energy necessary to achieve maximum processed density was about 22 mJ/cm².

### Example 13

The base coat formulation for Example 13 was prepared as described in Example 1 except that the amount of the infrared absorber, 2-[2-[2-thiophenyl-3-[2-(1,3-dihydro-1,3,3-trimethyl-2H-indol-2-ylidene)-ethylidene]-1-cyclohexen-1-yl]-ethenyl]-1,3,3-trimethyl-3H-indoliumchloride, was reduced to 0.0042 parts by weight and the 1-methoxy-2-propanol was increased to 55.0658 parts by weight. The base coat was applied and overcoat prepared and applied as described in Example 1. The plates were imaged as described in Example 1. In one case, the plate was directly processed with the developer described in Table 2 without a post-exposure heating step. The minimum exposure energy necessary to achieve maximum processed density was 79 mJ/cm². In another case, the plate was subjected to a post-exposure preheating step. During the post-exposure heating step the plate was passed through a Wisconsin oven set at 268° C. with a conveyor speed of 3 ft/min. This produced a temperature on the backside of the plate of 125° C. The plates were processed with the developer described in Table 2. The minimum exposure energy necessary to achieve maximum processed density in this case was 63 mJ/cm². By eliminating the post-exposure baking step, there is only about a 20% loss in minimum exposure energy necessary to reach maximum density. In Comparative Example 1, the difference between the preheated plates and the non-preheated plates was much greater than 150%. This example also illustrates the efficiency of this invention to effectively absorb enough infrared radiation during imaging to produce a satisfactory image, even with the infrared absorber content decreased nearly 20-fold.

### Examples 14-16

The base coat formulations for Examples 14, 15, and 16 were prepared as described in Example 1 with the exception that the following cellulose acetate propionate polymers (from Eastman Chemical Company) were used in place of Elvacite® 4026: CAP-540-0.2 (Example 14), CAP-482-0.5 (Example 15), and CAP-482-20 (Example 16). The acid number of these polymers was 0 mg KOH/g. The base coat was applied and overcoat prepared and applied and the plates were imaged and processed as described in Example 1. The minimum exposure energy necessary to achieve maximum processed density was about 25 mJ/cm² in Example 14, about 35 mJ/cm² in Example 15 and about 37 mJ/cm² in Example 16.

### Examples 17-21

Five coating formulations were prepared as detailed in Table 3. The solutions were applied to electrochemically grained and anodized aluminum substrates and dried to give a coating weight of 2 g/m².

TABLE 3
Composition of Examples 17-21 (formulations in parts by weight).

| | | | | Comparative | |
|---|---|---|---|---|---|
| | Example | Example | Example | Example | Example |
| Component | 17 | 18 | 19 | 20 | 21 |
| Reaction product of Desmodur ® | 3.56 | 3.56 | 3.56 | 3.56 | 3.56 |
| N100⁶ with hydroxyethyl | | | | | |
| acrylate and pentaerythritol | | | | | |
| triacrylate | | | | | |
| Joncryl ® 683¹ | 1.61 | 1.61 | 1.61 | 1.61 | 1.61 |
| Jagotex MA 2814² | 1.61 | 1.61 | 1.61 | 1.61 | 1.61 |
| Sartomer 355³ | 0.74 | 0.74 | 0.74 | 0.74 | 0.74 |
| 2-(4-methoxyphenyl)-4,6-bis | 0.39 | 0.39 | 0.39 | 0.39 | 0.39 |
| (trichloromethyl-s-triazine | | | | | |
| Phenoxyacetic acid | 0.21 | — | — | — | — |
| (2-Methoxyphenoxy) | — | 0.21 | — | — | — |
| acetic acid | | | | | |
| (3,4 Dimethoxyphenylthio) | — | — | 0.21 | — | — |
| acetic acid | | | | | |
| N-phenylglycine | — | — | — | 0.21 | — |
| Indole-3-acetic acid | — | — | — | — | 0.21 |
| IR dye⁴ | 0.13 | 0.13 | 0.13 | 0.13 | 0.13 |
| Crystal Violet | 0.10 | 0.10 | 0.10 | 0.10 | 0.10 |
| Byk ® 307⁵ | 0.02 | 0.02 | 0.02 | 0.02 | 0.02 |
| Methyl ethyl ketone | 13.74 | 13.74 | 13.74 | 13.74 | 13.74 |
| Toluene | 22.91 | 22.91 | 22.91 | 22.91 | 22.91 |
| 1-Methox-2-propanol | 54.98 | 54.98 | 54.98 | 54.98 | 54.98 |

¹Joncryl ® 683 is an acrylic acid copolymer available from S C Johnson & Son, Inc.
²Jagotex MA 2814 is an acrylic copolymer available from Ernst Jaeger GmbH & Co.
³Sartomer 355 is a multifunctional acrylic monomer available from Sartomer Co., Inc.
⁴The IR dye is 2-[2-[2-phenylthio-3-[(1,3-dihydro-1,3,3-trimethyl-2H-indol-2-ylidene) ethylidene)-1-cyclohexen-1-yl] ethenyl]-1,3,3-trimethyl-3H-indolium chloride.
⁵Byk ® 307 is a modified polysiloxane available from Byk Chemie.
⁶Desmodur ® N100 is an aliphatic polyisocyanate resin based upon hexamethylene diisocyanate, from Bayer Corporation, Milford, CT.

Each of the resulting coatings was then over-coated with a solution of 5.26 parts polyvinyl alcohol and 0.93 parts of polyvinylimidazole in 3.94 parts of isopropanol and 89.97 parts of water and dried to a final coating weight of 2 g/m².

Samples of coatings for Examples 17-19 were imaged on a Creo 3230, TRENDSETTER imagesetter at a power setting of 2 W from 20 to 120 mJ/cm². Example 20 was imaged on a Creo TRENSETTER imagesetter3244× at 4 W from 25 to 154 mJ/cm². Example 21 was imaged on a Creo TRENDSETTER imagesetter 3244× at 5 W from 52 to 500 mJ/cm². Example 17-21 plates were then processed with 980 Developer (from Kodak Polychrome Graphics) through a Technigraph processor equipped with a pre-development heating unit adjusted to bring the plate surface temperature to 125° C. Table 4 compares the maximum processed optical densities of the five plates in relation to the exposure dose required to obtain the observed result.

TABLE 4
Photosensitivity comparisons.

| | Exposure | Maximum Processed |
|---|---|---|
| Plate | (mJ/cm²) | Density |
| Example 17 | 84 | 0.92 |
| Example 18 | 93 | 0.84 |
| Example 19 | 88 | 0.79 |
| Comparative | 137 | 0.80 |
| Example 20 | | |
| Example 21 | 119 | 1.05 |

The results summarized in Table 4 show that the maximum optical densities of the processed coatings of the present invention and the minimum exposure necessary to reach the maximum processed density.

A sample of each plate was also incubated under accelerated aging conditions of 5 days at 38° C. and 80% relative humidity before being imaged and processed as above. The reflective density of each plate at the minimum exposure necessary to achieve maximum processed density was then measured and compared with the corresponding densities of the fresh plates to determine the percent loss in coating density. The results summarized in Table 5 show that the coatings of the present invention have good shelf life stability with respect to coating density loss upon aging.

TABLE 5
Effect of accelerated aging.

| | Exposure | Percent Coating |
|---|---|---|
| Plate | (mJ/cm²) | Density Loss |
| Example 17 | 269 | 24% |
| Example 18 | 112 | 19% |
| Example 19 | 111 | 15% |
| Comparative | 275 | 17% |
| Example 20 | | |
| Example 21 | 348 | 14% |

### Example 22

The base coat formulation for example 6 was prepared as described in example 17 except that in place of phenoxyacetic acid, 4-(dimethylamino) phenylacetic acid was substituted. The base coat was applied and the overcoat prepared and applied as described in example 17. Plates were imaged and processed as described in example 17. A maximum processed density of 0.55 was achieved at a minimum exposure energy of −130 mJ/cm² (the unprocessed density for this coating was 0.83, while for examples 1-5 the unprocessed density was about 1.0).

### Comparative Example 23

The coating formulation for comparative example 23 was prepared as detailed in example 17 except that phenoxyacetic acid was omitted. The solutions were applied to electrochemically grained and anodized aluminum substrates and dried to give a coating weight of 2 g/m².

The resulting coatings was then over-coated with a solution of 5.26 parts polyvinyl alcohol and 0.93 parts of polyvinylimidazole in 3.94 parts of isopropanol and 89.97 parts of water and dried to a final coating weight of 2 g/m².

A sample of coating was imaged on a Creo 3230 TRENDSETTER imagesetter at a power setting of 10 W from 100 to 800 mJ/cm². The plate was then processed with 980 Developer (from Kodak Polychrome Graphics) through a Technigraph processor equipped with a pre-development heating unit adjusted to bring the plate surface temperature to 125° C. The minimum exposure energy necessary to achieve maximum processed density was ˜300 mJ/cm² with a processed density of 0.78. This example shows that the hetero-substituted arylacetic acid coinitiators of the present invention substantially improve the photo speed over that which would otherwise be obtained in their absence.

The present invention has been described with particular reference to the preferred embodiments. It should be understood that variations and modifications thereof can be devised by those skilled in the art without departing from the spirit and scope of the present invention. Accordingly, the present invention embraces all such alternatives, modifications and variations that fall within the scope of the appended claims.

1. A lithographic printing plate precursor comprising:
a substrate; and coated on the substrate, an infrared radiation-sensitive composition comprising:
a polymeric binder,
a free radical polymerizable system consisting of at least one polymerizable component,
a compound capable of absorbing infrared radiation, an initiator system comprising an iodonium salt that is capable of producing free radicals; and
at least 1% and up to and including 10% by weight, based on the infrared-sensitive composition, of at least one carboxylic acid having an aromatic moiety that is represented by:
(1) formula (A), (B), or (C): 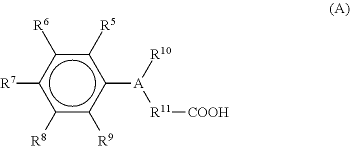
wherein each of R⁵, R⁶, R⁷, R⁸ and R⁹ is independently selected from the group consisting of hydrogen, alkyl, aryl, halogen, alkoxy, hydroxyalkyl, carboxyalkyl, alkylthio, alkylsulfonyl, sulfonic, alkylsulfonate, dialkylamino, acyl, alkoxycarbonyl, cyano, and nitro, or R⁵ and R⁶, R⁶ and R⁷, R⁷ and R⁸, or R⁸ and R⁹ together optionally form an aromatic or aliphatic ring,
R¹⁰ is selected from the group consisting of hydrogen, alkyl, aryl, hydroxyalkyl, carboxyalkyl, acyl, alkoxycarbonyl, alkylsulfonyl, and alkylsulfonate, or R¹⁰ and its bond together optionally form an electron pair, or R⁹ and R¹¹ together optionally form a ring, R¹¹ is an alkylene group of C₁-C₆ carbon atoms, or R¹⁰ and R¹¹ together optionally form an aliphatic ring, and
A is a heteroatom selected from the group consisting of N, O, and S; 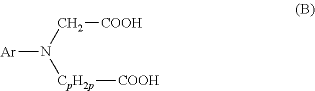
wherein Ar is selected from the group consisting of an unsubstituted aryl, a mono-substituted aryl, and a poly-substituted aryl group, and p is an integer from 1 to 5; 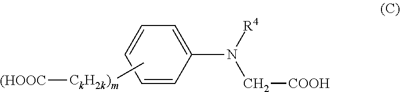
wherein R⁴ is selected from the group consisting of hydrogen and a C₁-C₆ alkyl group, and wherein each of k and m is independently an integer from 1 to 5;
(2) a combination of compounds represented by formulae (A), (B), and (C); or
(3) a carboxylic acid having an aromatic moiety and that is represented by one of the following structures: 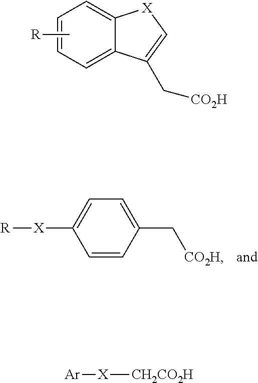
wherein X is NR′, oxygen, or sulfur, Ar is any substituted or unsubstituted aryl ring. R′ is hydrogen or an alkyl group, and R is any substituent.

2. The lithographic printing plate precursor of claim 1 wherein the polymeric binder has a total acid number of 70 mg KOH/g or less.

3. The lithographic printing plate precursor of claim 1 further comprising an oxygen-impermeable overcoat disposed over the infrared radiation sensitive composition.

4. The lithographic printing plate precursor of claim 1 wherein the polymeric binder is selected from the group consisting, of a polymer derived from an acrylic ester, a cellulose polymer, and a combination thereof.

5. The lithographic printing plate precursor of claim 1 wherein the polymeric binder has a total acid number of 50 mg KOH/g or less.

6. The lithographic printing plate precursor of claim 1 wherein the polymeric binder has a total acid number is 30 mg KOH/g or less.

7. The lithographic printing plate precursor of claim 1 wherein the polymeric binder has a total acid number is 10 mg KOH/g or less.

8. The lithographic printing plate precursor of claim 1 wherein the polymerizable component comprises a monomer, oligomer, or prepolymer derived from acrylic or methacrylic acid.

9. The lithographic printing plate precursor of claim 1 wherein the compound capable of absorbing infrared radiation is selected from the group consisting of triarylamine dyes, thiazolium dyes, indolium dyes, oxazolium dyes, cyanine dyes, polyaniline dyes, polypyrrole dyes, polythiophene dyes, leuco dyes, phthalocyanine pigments and dyes, and a combination thereof.

10. The lithographic printing plate precursor of claim 1 wherein the iodonium salt is a diaryliodonium salt.

11. The lithographic printing plate precursor of claim 1 wherein the carboxylic acid having an aromatic moiety is a monocarboxylic acid.

12. The lithographic printing plate precursor of claim 1 wherein the carboxylic acid having an aromatic moiety is a polycarboxylic acid.

13. A method of preparing a lithographic printing plate comprising:
imagewise exposing the lithographic printing plate precursor of claim 1 to infrared radiation to provide an imaged precursor, and
processing the imaged precursor to provide a lithographic printing plate.
